(19) United States
(12) Patent Application Publication
(10) Pub. No.: US 2005/0085031 A1
(43) Pub. Date: Apr. 21, 2005

(54) Heterogeneous activation layers formed by ionic and electroless reactions used for IC interconnect capping layers

(75) Inventors: Sergey D. Lopatin, Santa Clara, CA (US); Arulkumar Shanmugasundram, Sunnyvale, CA (US); Yosef Shacham-Diamand, Ithaca, NY (US); Timothy Weidman, Sunnyvale, CA (US); Dmitry Lubomirsky, Cupertino, CA (US)

Correspondence Address: MOSER, PATTERSON & SHERIDAN, LLP/;APPLIED MATERIALS, INC., 3040 POST OAK BOULEVARD, SUTIE 1500, HOUSTON, TX, 77056, US

(73) Assignee: APPLIED MATERIALS, INC.

(21) Appl. No.: 10/967,099

(22) Filed: Oct. 15, 2004

Related U.S. Application Data
(60) Provisional application No. 60/511,993, filed on Oct. 15, 2003.

(51) Int. Cl. H01L 21/8238

(52) U.S. Cl. 438/222

(57) ABSTRACT

Embodiments of the invention generally provide compositions of activation-alloy solutions, methods to deposit activation-alloys and electronic devices including activation-alloys and capping layers. In one embodiment, a method for depositing a capping layer for a semiconductor device is provided which includes exposing a conductive layer on a substrate surface to an activation-alloy solution, forming an activation-alloy layer on the conductive layer using the activation-alloy solution, and depositing the capping layer on the activation-alloy layer using an electroless deposition solution.

### CROSS-REFERENCE TO RELATED APPLICATIONS

This application claims benefit of U.S. Provisional Patent Application Ser. No. 60/511,993, filed Oct. 15, 2003, which is herein incorporated by reference.

### BACKGROUND OF THE INVENTION

1. Field of the Invention

Embodiments of the invention generally relate to methods for depositing capping layers within a feature, formed as part of an electronic device, and more particularly to methods for depositing an alloy-activation layer to a conductive surface.

2. Description of the Related Art

Recent improvements in circuitry of ultra-large scale integration (ULSI) on substrates indicate that future generations of semiconductor devices will require multi-level metallization with smaller geometric dimensions. The multilevel interconnects that lie at the heart of this technology require planarization of interconnect features formed in high aspect ratio features, including contacts, vias, lines and other features. Reliable formation of these interconnect features is very important to the success of ULSI and to the continued effort to increase circuit density and quality on individual substrates and die as features decrease in size.

Currently, copper and its alloys have become the metals of choice for sub-micron interconnect technology because copper has a lower resistivity than aluminum, (1.67 μΩ-cm for copper compared to 3.1 μΩ-cm for aluminum, at room temperature), significantly higher electromigration and stress voiding resistance. Therefore, copper has a higher current carrying capacity and higher operation temperature. These characteristics are important for supporting the higher current densities experienced at high levels of integration and increased device speed. Further, copper has a good thermal conductivity and is available in a highly pure state. Finally, copper interconnect processes seem to have a lower cost of production when compared to aluminum technologies.

Electroless deposition is a process used to deposit thin films, such as metals, semiconductors and insulators. Electroless deposition uses auto catalyzed chemical electrochemical deposition processes that does not require an applied external current to initiate the reaction. Electroless deposition typically involves exposing a substrate to a solution by either immersing the substrate in a bath or by spraying or flowing a solution onto the substrate.

However, copper readily forms copper oxide when exposed to water and atmospheric conditions or environments outside of processing equipment and requires a passivation layer to prevent metal oxide formation. Metal oxides can result in an increase in the resistance of metal layers, become a source of particles and reduce the reliability of the overall circuit.

One solution to minimize oxidation effects is to deposit a capping layer on the metal layer to prevent metal oxide formation. Cobalt alloys have been observed as suitable materials for capping copper and may be deposited by electroless deposition techniques. However, copper does not satisfactorily catalyze or initiate deposition of materials from electroless solutions, when the materials have an electrochemical reduction potential lower than copper. For example, cobalt has a reduction potential of −0.26 eV, while copper has a reduction potential of 0.34 eV, each referenced to a standard hydrogen electrode (SHE). One approach to catalyze or initiate deposition of cobalt or nickel and their alloys on copper is to deposit from an electroless solution by contacting the copper substrate with a more electropositive metal such as aluminum or zinc which initiates deposition through a galvanic reaction. However, the process requires a continuous conductive surface over the substrate surface that may not be available with some passivation applications.

Another approach is to activate the copper surface by depositing a catalytic material on the copper surface. However, deposition of the catalytic material may require multiple steps or use catalytic colloid compounds. Catalytic colloid compounds may adhere to dielectric materials and result in undesired, excessive and non-selective deposition of the passivation material on the substrate surface. Non-selective deposition of passivation material may lead to surface contamination, unwanted diffusion of conductive materials into dielectric materials, and even device failure from short circuits and other device irregularities.

An activated layer is deposited between a conductive layer and a capping layer to provide strong adhesion among these layers. Generally, the activated layer is composed of a single, noble metal, such as a palladium or platinum. An interface is formed between the conductive layer and the activated layer, for example, two distinguishable layers, such as a copper conductive layer and a noble metal activation layer, form an interface. The interface is susceptible to adhesion slippage, increased electrical resistance and subsequent oxidation. Metal oxides on the conductive layer are undesirable because of the increased electrical resistivity.

High electromigration (EM) resistance is a reliability requirement that is critical for high-density interconnect (IC) devices. Copper EM in damascene interconnections can be significantly reduced with the capping layers. However, anticipated RC reduction of such ICs with low-k materials requires the capping layers to have barrier properties to prevent copper diffusion. The temperature for a back end of line (BEOL) process and packaging can reach 450° C., which can lead to oxidation of cobalt alloys or palladium layers and copper diffusion through these layers.

CoW alloys are selectively deposited by electroless deposition on the conductive layer after a CMP process. The interface should be free of defects. The quality of the conductive layer after the CMP process depends on the degree of its resistance to corrosion effects. Post CMP corrosion of copper occurs and results in defects of accelerated copper oxidation and etching, especially pronounced along grain boundaries and interfaces with a barrier layer. Corrosion of the copper increases the electrical resistance of the IC device.

Therefore, there is a need for a method and composition to form an electroless layer, such as a capping layer with strong adhesion to a conductive layer, low electrical resistance and strong barrier properties.

### SUMMARY OF THE INVENTION

In one embodiment, a method for depositing a capping layer is provided which includes exposing a conductive feature on a substrate surface to an activation-alloy solution to form an activation-alloy layer on the conductive layer, and depositing a capping layer on the activation-alloy layer using an electroless deposition solution.

In another embodiment, a method for depositing a capping layer is provided which includes forming an activation-alloy layer on a copper layer disposed on a substrate surface, and exposing the activation-alloy layer to a capping solution to deposit the capping layer on the activation-alloy layer.

In another embodiment, a composition of a deposition solution for depositing an activation-alloy is provided which includes a copper source in a range from about 10 mM to about 100 mM, a cobalt source in a range from about 50 mM to about 500 mM, a complexing agent in a range from about 100 mM to about 700 mM and a pH adjusting agent to adjust the pH of the deposition solution with a pH in a range from about 7 to about 12.

In another embodiment, a composition of a deposition solution for depositing an activation-alloy is provided which includes a copper source in a range from about 10 mM to about 100 mM, a palladium source in a range from about 50 mM to about 500 mM, a complexing agent in a range from about 100 mM to about 700 mM and a pH adjusting agent in a range from about 50 mM to about 500 mM.

In another embodiment, an electronic device structure is provided which includes a conductive layer disposed on a barrier layer disposed in a substrate, an activation-alloy layer disposed on the conductive layer and a CoW alloy layer disposed on the activation-alloy.

In another embodiment, a method for depositing a capping layer is provided which includes performing an ALD process to form a ruthenium-containing activation layer on a copper layer disposed on a substrate surface, and exposing a capping solution to the substrate surface to deposit the capping layer on the ruthenium-containing activation layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C show a step-wise formation an interconnect structure;

FIG. 2 is a flow chart illustrating a process to form an interconnect structure;

FIGS. 3A-3C show another step-wise formation an interconnect structure;

FIG. 4 is a flow chart illustrating another process to form an interconnect structure; and

FIG. 5 shows an electronic feature.

### DETAILED DESCRIPTION OF THE PREFERRED EMBODIMENT

The words and phrases used herein should be given their ordinary and customary meaning in the art as understood by one skilled in the art unless otherwise further defined. Electroless deposition is broadly defined herein as deposition of a conductive material by a replacement reaction or exchange reaction wherein ions in a solution replace metal atoms on a surface while the metal atoms are ionized into the solution. Also, electroless deposition is broadly defined herein as deposition of a conductive material by ions in a bath over a catalytically active surface to deposit the conductive material by chemical reduction in the absence of an external electric current, such as in an autocatalytic reaction.

The invention generally provides an activation treatment that avoids corrosion of a conductive layer, such as copper, that occurs between a CMP process and deposition of an electroless capping layer. The treatment forms an activation-alloy on the conductive surface by at least one of several processes, such as ion contact displacement, electroless deposition, ion implantation or atomic layer deposition (ALD). The invention further provides processes to deposit a capping layer.

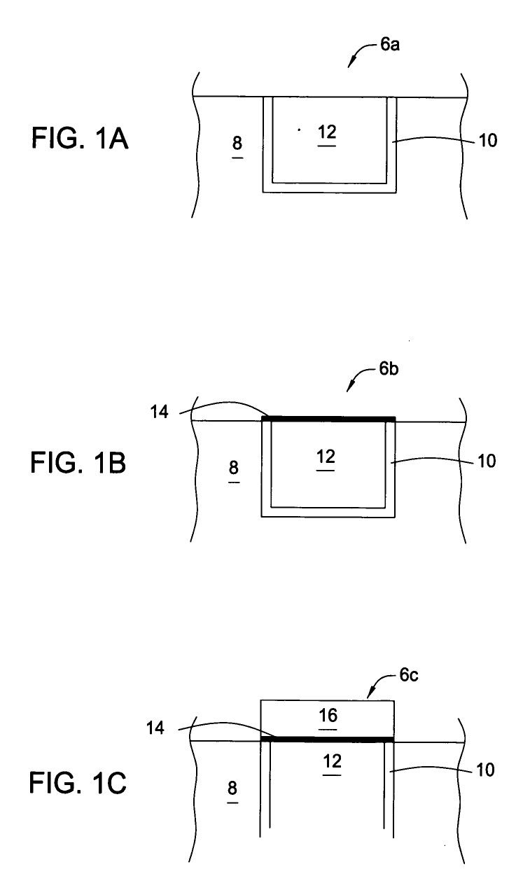

FIG. 1A shows a cross-sectional view of an interconnect 6a having a conductive material 12 disposed into low-k material 8. Conductive material 12 includes metals, such as copper, silver, aluminum, tungsten, platinum, palladium, various alloys of the aforementioned metals and combinations thereof. Preferably, conductive material 12 is copper or a copper alloy. The conductive material 12 is generally deposited by a deposition process, such as electroplating, electroless plating, physical vapor deposition (PVD), chemical vapor deposition (CVD), ALD and/or combinations thereof. As depicted in FIG. 1A, conductive material 12 can be polished or leveled, such as by a chemical mechanical polishing (CMP). A barrier layer 10 separates low-k material 8 from the conductive material 12. Low-k material 8 may include features, such as electrodes or interconnects, throughout the layer (not shown). Barrier layer 10 is usually a material that includes tantalum, tantalum nitride, tantalum silicon nitride, titanium, titanium nitride, titanium silicon nitride, tungsten nitride, silicon nitride and combinations thereof. Barrier layer 10 is usually deposited by a PVD, ALD or CVD process.

Interconnect 6a, as well as other semiconductor features, are formed on a substrate. Substrates on which embodiments of the invention may be used to advantage include, but are not limited to semiconductor wafers, such as crystalline silicon (e.g., Si<100> or Si<111>), silicon on insulator, silicon oxide, silicon germanium, doped or undoped polysilicon, doped or undoped silicon wafers, silicon nitride and patterned or non-patterned wafers. Surfaces may include bare silicon, films, layers and materials with dielectric, conductive or barrier properties. Pretreatment processes may include one or more of polishing (e.g., CMP), electrochemical plating (ECP), etching, reduction, oxidation, hydroxylation, annealing and baking. The term substrate surface is used herein to refer to any semiconductor feature present thereon, including the exposed surfaces of the features, such as the wall and/or bottom of vias, dual damascene structures, contact holes and the alike.

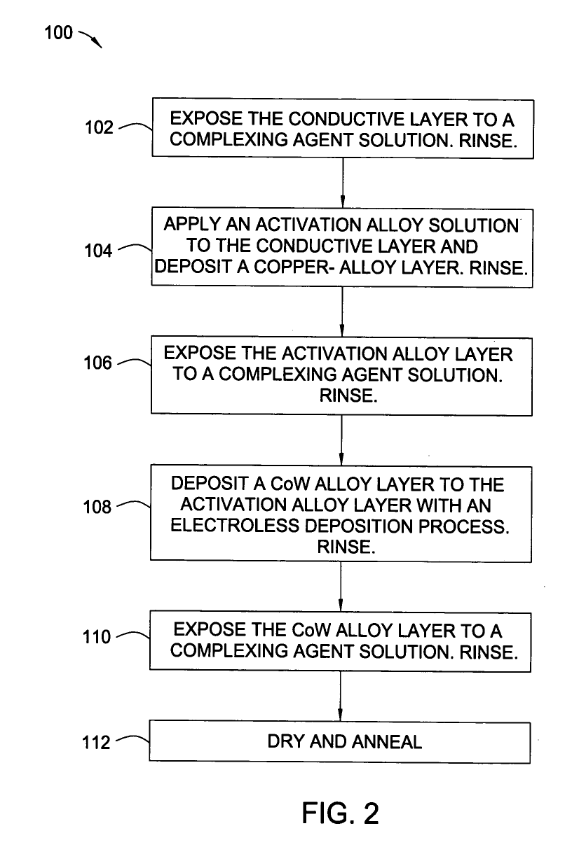

FIGS. 1A-1C are cross-sectional views of interconnect 6 resulting from steps taken during a process 100 shown in FIG. 2. During step 102, the substrate is exposed to a complexing solution to remove oxides, residues and/or contaminates left from a previous fabrication process (e.g., CMP). Contaminants include oxides, copper oxides, copper-organic complexes, silicon oxides, organic residues (e.g., benzotriazole), resist, polymeric residue, derivatives thereof and combinations thereof. The exposure time of the complexing solution will range from about 5 seconds to about 120 seconds, preferably from about 10 seconds to about 30 seconds and more preferably for about 20 seconds. The complexing solution treats the exposed surface and removes contaminates from conductive material 12, barrier layer 10 and low-k material 8.

The complexing agent solution is an aqueous solution containing at least one complexing agent, such as citric acid, EDTA, EDA, various carboxylic acids and combinations thereof and derivatives thereof. The solution may contain additives such as surfactants to improve wetting. Other additives, such as levelers, brighteners, accelerators, inhibitors, among others may also be used. In another embodiment, the complexing agent solution contains citric acid with a concentration in a range from about 1 mL/L to about 40 mL/L, preferably from about 5 mL/L to about 15 mL/L. In another embodiment, the complexing agent solution contains EDTA with a concentration in a range from about 1 mL/L to about 40 mL/L, preferably from about 5 mL/L to about 15 mL/L.

Following exposure of the substrate to the complexing agent solution, the substrate surface is rinsed. The rinse step includes washing any remaining complexing solution and/or contaminants from the surface with deionized water. The substrate will be rinsed for a period of about 1 second to about 120 seconds, preferably for about 5 seconds to about 30 seconds.

During step 104, the substrate is exposed to an activation-alloy solution to form an activation-alloy layer 14, as depicted in FIG. 1B. The exposure time of the activation-alloy solution to the substrate will range from about 1 second to about 60 seconds, preferably from about 10 seconds to about 30 seconds and more preferably for about 20 seconds. The activation-alloy layer 14 is deposited to the conductive material 12. The activation-alloy layer 14 may be a continuous layer or a discontinuous layer across the surface of conductive material 12. The activation-alloy layer 14 may have a thickness from about a single atomic layer to about 100 Å, preferably from about 3 Å to about 20 Å. In one embodiment, the activation-alloy layer 14 is deposited discontinuously across the exposed surface of conducting material 12. In another embodiment, the activation-alloy layer 14 is deposited continuously across the exposed surface of conducting material 12.

An activation-alloy layer 14 provides an active surface on which a subsequent capping layer can be deposited. Activation-alloys may be binary alloys, but often include tertiary alloys, quaternary alloys and pentanary alloys. Activation-alloys include metals such as copper, palladium, platinum, nickel, cobalt, rhodium, iridium, silver, gold, zinc, tungsten, molybdenum, ruthenium and combinations thereof. Examples of activation-alloys include PdCu, PdCo, PdNi, CoCu, CoNi, NiCu, CoRh, CoCuW, PdCuW, PdCoW, PdNiW, CoNiW, NiCuW, CoPdCuNi, CoPdAgCuNi, RuCo, RuCo, RuCuW containing varying elemental ratios. In one embodiment, tungsten is in a PdCuW-alloy with an atomic concentration range from about 2% to about 8%, preferably about 6%. In another embodiment, tungsten is in a CoCuW-alloy with an atomic concentration range from about 2% to about 8%, preferably at about 6%. In one example, a CoCu alloy has a copper/cobalt ratio concentration of about 10. In another aspect, a CoCu alloy has a copper/cobalt ratio concentration of about 20, such that the cobalt concentration inhibits the corrosion of the copper.

Activation-alloys may also contain additive elements, such as boron, phosphorus, carbon, sulfur, nitrogen and combinations thereof. For example, some PdCu activation-alloys containing additive elements include PdCuS, PdCuP, PdCuB, PdCuSP, PdCuSB, PdCuPB and PdCuSPB. Other activation-alloys of CoCu include CoCuS, CoCuP, CoCuB, CoCuSP, CoCuSB, CoCuPB and CoCuSPB. In one example, an activation-alloy layer of PdCuS is deposited with a discontinuous layer of PdCu-alloy and a discontinuous layer of sulfur. Therefore, islands of PdCu-alloys and sulfur are formed across the conductive material.

In one embodiment, an activation-alloy solution displaces at least a portion of the conductive material to form an activation-alloy layer. Displacement is a deposition technique in which a layer, such as a monolayer, on a surface is replaced with a layer, such as a monolayer, of another material or element. Generally, displacement reactions are self limiting, because once a monolayer of a replacement material or element is formed, the surface of the host material or element to be displaced is not exposed to the displacement solution.

Displacement solutions comprise at least two metal sources and at least one acid. Metal sources include metal salts (e.g., SO₄, PO₃, CH₃CO₂, or NO₃), metal halides (e.g., F, Cl, Br or I), organometallics (e.g., carbonyl complexes) with a metal, such as copper, palladium, platinum, nickel, cobalt, rhodium, iridium, silver, gold, zinc, tungsten, molybdenum and combinations thereof. The metal sources may have a concentration in a range from about 100 ppm to about 1 atomic percent, preferably from about 500 ppm to about 0.1 atomic percent. Acids include HCl, HF, H₂SO₄, H₃PO₃, derivatives thereof and combinations thereof. The acid may have a concentration from about 0.5 mL/L to about 20 mL/L, preferably from about 1 mL/L to about 10 mL/L. In one example, HCl, HF and H₂SO₄ are used in the same solution.

In one embodiment, a contact displacement solution is used to deposit a PdCu alloy on a copper-containing conductive underlayer. A PdCu alloy is usually deposited as a smooth, even layer with little to no satellites as opposed to a pure palladium activation layer, which may form nanoclusters across the conductive underlayer. The PdCu alloy may contain a palladium to copper atomic ratio of about 1,000:1, about 100:1 or about 10:1. Wishing not to be bound by theory, it is believed that during the displacement reaction, copper atoms from the conductive underlayer are replaced by palladium atoms. However, due to several controllable variables in the displacement reaction solution, including the copper ion concentration, the pH and chelators, the displacement reaction reaches an equilibrium and forms the PdCu alloy by limiting copper displacement by palladium. The addition of copper ions in the displacement solution tends to limit the grain growth of the palladium.

A displacement solution may be formed by combining a palladium solution and a copper solution at various ratios. A palladium solution includes a palladium source and at least one acid, such as HCl, H₂SO₄, HF and combinations thereof. A copper solution includes a copper source and acids. A chelator may be added to either or both of the palladium and copper solutions, such as a carboxylic acid, preferably a multi-functionalized carboxylic acid and salts thereof. Chelators include acetate, benzoate, citrate, tartrate, EDTA, salts thereof, derivates thereof and combinations thereof, preferably ammonium acetate. A pH adjusting agent may be added to maintain a pH of about 2 to about 9 of either or of the both palladium and copper solutions. In one example, a Pd solution may include PdCl₂ (150 g/L), [NH₄][CH₃CO₂] (90 g/L), HCl (100 g/L), HF (10 mL/L) and deionized water. A Cu solution may include CUSO₄ (50 g/L)[NH₄][CH₃CO₂] (250 g/L), H₂SO₄ (30 g/L), HCl (50 ppm) and deionized water. In one aspect, the Pd solution (100 mL), the Cu solution (20 mL) and deionized water (880 mL) are combined to produce a displacement solution.

Contact displacement solutions may include other additives, such as pH buffers and wetting agents. The pH of the displacement solution effects the deposition rate, therefore, pH buffers are added to the solution to limit sudden fluctuations of the pH. Although chelators and/or pH additives in combination or independently may contribute to pH buffering, other pH buffers, such as stabilizers may be included, such as (CH₃CO₂)₂Pd, (CH₃CO₂)₂Cu, (CH₃CO₂)₂Ni, derivatives thereof, hydrates thereof and combinations thereof. Stabilizers may be dissolved in dilute acidic solutions, such as H₂SO₄, HCl and deionized water before adding to the displacement solution. Generally, the stabilizers have a concentration from about 10 ppm to about 1,000 ppm, preferably from about 100 ppm to about 500 ppm. Wetting agents may be added to the displacement solution with a concentration from about 1 ppm to about 1,000 ppm, preferably from about 10 ppm to about 100 ppm. Wetting agents include surfactants, such as Triton X-100 or Rhodafac RE-610. Contact displacement solutions are generally acidic and may have a pH in the range from about 1 to about 7, preferably from about 2 to about 3.

In another embodiment, an electroless activation-alloy solution may be used to control the composition (atomic ratio) when depositing an activation-alloy layer on a conductive layer. For example, a PdCu alloy may contain about 15:1 (atomic) palladium to copper within the activation-alloy layer. In one aspect, a PdCu alloy layer is deposited discontinuously across the conductive material.

An activation-alloy solution, used for electroless deposition, may be an aqueous solution (deionized water) that includes at least two metal sources, at least one complexing agent, a reducing agent, a pH adjusting agent and a surfactant. Metal sources usually have a metal concentration in the range from about 0.1 mM to about 250 mM, preferably from about 1 mM to about 150 mM, and more preferably, from about 10 mM to about 100 mM. Metal sources may include compounds and/or complexes of copper, palladium, cobalt, tungsten, rhodium, nickel, iridium, ruthenium, osmium, platinum and combinations thereof. Copper sources include copper sulfate (CuSO₄.5H₂O), copper chloride (CuCl or CuCl₂), copper citrate, copper acetate, derivatives thereof and combinations thereof. Palladium sources include palladium sulfate, (PdSO₄.7H₂O), palladium chloride, palladium nitrate, palladium acetate, palladium 2,4-pentanedionate. Cobalt sources include cobalt chlorides (e.g., COCl₂.6H₂O), cobalt sulfates (e.g., CoSO₄.7H₂O) and combinations thereof.

Complexing agents may be added to the activation-alloy solution with a concentration from about 50 mM to about 500 mM, preferably from about 150 mM to about 380 mM. Complexing agents form chelated metal ions (e.g., Co²⁺, Cu²⁺ or Pd²⁺) with a lower dissociation constant than the free metallic ion. Complexing agents include carboxylic acids, such as EDTA, EDA, citric acid, tartaric acid, derivatives thereof and combinations thereof. In one example, citric acid and tartaric acid are in the activation-alloy solution each with a concentration in the range from about 30 g/L to about 70 g/L, preferably about 50 g/L. In another example, tartaric acid is in the activation-alloy solution, each in with a concentration in the range from about 30 g/L to about 70 g/L, preferably about 50 g/L. In another example, EDTA is in the activation-alloy solution in a concentration in the range from about 30 g/L to about 70 g/L, preferably about 50 g/L.

Reducing agents or reductants may be added to the activation-alloy solution in a concentration from about 1 mM to about 200 mM, preferably from about 10 mM to about 100 mM. Reductants chemically reduce (i.e., transfer electrons to) solvated metal ions in the plating solution to initiate the electroless plating process. The reduction process precipitates the various elements and/or compounds to form the composition of the activation-alloys, such as cobalt, copper and palladium, among other elements. Reducing agents useful in the invention include hypophosphorous acid, glyoxylic acid, hydrazine, diborane, borane complexes, salts thereof, derivatives thereof, complexes thereof and combinations thereof. Borane complexes have at least one ligand, such as amines, phosphines, solvents and other compounds that have Lewis base characteristics. Once dissolved in a solution, borane complexes dissociate to produce free borane and/or borane complexes with other ligands. Borane complexes include dimethylamine borane complex ((CH₃)₂NH.BH₃), DMAB), trimethylamine borane complex ((CH₃)₃N.BH₃), TMAB), tert-butylamine borane complex (^{t}BuNH₂.BH₃), triethylamine borane complex ((CH₃CH₂)₃N.BH₃), tetrahydrofuran borane complex (THF.BH₃), pyridine borane complex (C₅H₅N.BH₃), ammonia borane complex (NH₃.BH₃), borane (BH₃), diborane (B₂H₆), derivatives thereof, complexes thereof and combinations thereof.

Generally, pH adjusting agents, such as bases and acids, are added to adjust the pH of the activation-alloy solution. Bases used to increase the pH of the activation-alloy solution include hydroxides, amines and hydrides, such as TMAH, ammonium hydroxide (NH₄OH), dimethylamine ((CH₃)₂NH), triethanolamine ((HOCH₂CH₂)₃N, TEA), diethanolamine ((HOCH₂CH₂)₂NH, DEA), and combinations thereof. Bases are used to maintain the solution within a pH from about 7 to about 12, preferably from about 8 to about 10. In one example, NH₄OH is in the activation-alloy solution in a concentration in the range from about 5 g/L to about 100 g/L, preferably from about 20 g/L to about 25 g/L. In another example, 25 vol % TMAH is in the activation-alloy solution in a concentration in the range from about 5 g/L to about 100 g/L, preferably from about 20 g/L to about 25 g/L. Acids are used to decrease the pH and include hydrochloric acid, sulfuric acid, acetic acid, nitric acid, hydrofluoric acid and combinations thereof.

Elemental additives within an activation-alloy solution may include tungsten, sulfur, phosphorus, boron, nitrogen and combinations thereof. Elemental additives may be added to the solution in a concentration from about 0% to about 20%, preferably from about 0.1% to about 10%. Tungsten may be added to an activation-alloy solution from a tungsten source, such as calcium tungstate (CaWO₄), ammonium tungstate ((NH₄)₂WO₄), tungstic acid (H₂WO₄), other WO₄²⁻ sources, derivatives thereof and combinations thereof. Sulfur may be added to an activation-alloy from a sulfur source, such as sulfates or organic sulfur compounds including disulfides, mercaptans, thiols and combinations thereof. Phosphorus may be added to an activation-alloy solution from a phosphorus source, such as H₃PO₂, other PO₂³⁻ sources, salts thereof, derivatives thereof and combinations thereof. Boron may be added to an activation-alloy solution from a boron source, such as a borane compound or complex (e.g., DMAB).

Activation-alloy solutions deposit activation-alloys by ion contact displacement processes and electroless deposition processes. Contact displacement solutions are generally acidic and have a dilute metal ion concentration (e.g., ppm). Electroless deposition solutions are generally basic, are more concentrated than displacement solutions (e.g., mM) and contain a reducing agent. For example, an ion contact displacement solution for depositing a PdCu-alloy with a pH in a range from about 2.0 to about 3.5 may be mixed by combining aqueous solutions into deionized water, such as 5% PdCl₂ at a concentration in a range from about 0.2 mL/L to about 0.6 mL/L; 36% HCl at a concentration in a range from about 2 mL/L to about 5 mL/L; 49% HF at a concentration in a range from about 5 mL/L to about 12 mL/L; 5% CUSO₄ at a concentration in a range from about 0.01 mL/L to about 0.1 mL/L; 98% H₂SO₄ at a concentration in a range from about 2 mL/L to about 5 mL/L; and a surfactant (e.g., polyoxyethylene nonylphenyl ether, phosphate) at a concentration at about 0.02 mL/L or less, preferably, about 0.001 mL/L or less, for example, in a range from about 1 ppm to about 20 ppm. In another example, an electroless deposition solution for depositing a CuCo-alloy with a pH in a range from about 8.0 to about 12.5 may be mixed in deionized water by combining CuSO₄.5H₂O at a concentration in a range from about 3 g/L to about 5 g/L; COSO₄.7H₂O at a concentration in a range from about 0.3 g/L to about 1 g/L; EDTA at a concentration in a range from about 5 g/L to about 15 g/L; glyoxylic acid at a concentration in a range from about 0.5 g/L to about 2 g/L; TMAH at a concentration in a range from about 20 g/L to about 25 g/L; a surfactant (e.g., polyoxyethylene nonylphenyl ether phosphate) at a concentration at about 0.02 mL/L or less, preferably, about 0.001 mL/L or less, for example, in a range from about 1 ppm to about 20 ppm; optional DMAB at a concentration in a range from about 0.2 g/L to about 0.5 g/L; and optional (NH₄)₂WO₄ at a concentration in a range from about 0.2 g/L to about 0.4 g/L. The optional boron source and/or tungsten source may be added to the solution to deposit alloys, such as CuCoB, CuCoW or CuCoWB.

Following exposure of the substrate to the activation-alloy solution, the substrate surface is rinsed. The rinse step includes washing any remaining activation-alloy solution and/or contaminants from the surface with deionized water. The substrate will be rinsed for a period from about 1 second to about 30 seconds, preferably from about 5 seconds to about 10 seconds.

The activation-alloy layer 14 is exposed to a complexing agent solution during step 106. The complexing agent solution further cleans the substrate surface and removes remaining contaminants from any of the early processes. Complexing agents are useful to chelate with metal ions, such as copper, cobalt and/or palladium. Generally, the substrate surface is exposed to the complexing agent solution for a period from about 5 seconds to about 60 seconds, preferably from about 15 seconds to about 30 seconds. The complexing agent solution is an aqueous solution as described in step 102.

Following exposure of the substrate to the complexing agent solution, the substrate surface is rinsed. The rinse step includes washing any remaining complexing solution and/or contaminants from the surface with deionized water. The substrate will be rinsed for a period in a range from about 1 second to about 30 seconds, preferably from about 5 seconds to about 10 seconds.

A CoW alloy layer 16 is deposited to the activation layer 14 via an electroless process, as depicted in FIG. 1 to form a capping layer. The CoW alloy layer 20 is deposited during step 108 by exposing activation layer 14 to a CoW solution. The CoW alloy layer may include a variety of alloys containing cobalt, tungsten, boron, phosphorus and combinations thereof. Examples of CoW alloys include CoW, CoWB, CoWP and CoWBP, wherein each elemental ratio varies. Generally, CoW alloys have a composition in weight percent, such as a cobalt concentration in a range from about 85% to about 95%, preferably from about 88% to about 90%, a tungsten concentration in a range from about 1% to about 8%, preferably from about 2% to about 4%, a boron concentration in a range from about 0% to about 6%, preferably from about 3% to about 4% and a phosphorus concentration in a range from about 0% to about 12%, preferably from about 6% to about 8%. In one example, a CoWBP alloy with a cobalt concentration from about 88% to about 90% is deposited to a PdCuS activation layer. The CoWBP may be about 70 Å thick and the PdCuS may be about 10 Å thick.

The concentration of phosphorus and/or boron within a CoW alloy layer can determine the degree the layer is amorphous. Generally, barrier properties (i.e., stop diffusion of copper or oxygen) increase as the layer becomes more amorphous. Boron is incorporated into a CoW alloy to add bond strength and density to the alloy. Phosphorus is incorporated into a CoW alloy to allow a deposited structure of nanocrystalline material embedded in an amorphous matrix, to increase the phase transition temperature where the material becomes fully polycrystalline, to limit grain growth and to stuff the grain boundaries preventing copper grain boundary diffusion. Therefore, each element, boron and phosphorus, has distinct attributes while simultaneously manipulating the barrier properties of a CoW alloy layer.

In step 108, a CoW solution is exposed to the activation layer 14 to deposit a CoW alloy layer 20. Generally, the substrate is exposed to a CoW solution for a period in the range from about 5 seconds to about 90 seconds, preferably, from about 20 seconds to about 45 seconds. A CoW alloy layer is deposited to a thickness of about 1,000 Å or less, preferably about 500 Å or less and more preferably about 150 Å or less. For example, a CoW alloy layer may have a thickness from about 5 Å to bout 120 Å, preferably about 60 Å. A CoW solution is usually maintained at a temperature in the range from about 50° C. to about 95° C. and has a pH in the range from about 7 to about 11, preferably, from about 8 to about 10 and more preferably about 9.

A CoW solution is an aqueous solution (deionized water) that includes a cobalt source, a tungsten source, complexing agent, a buffering compound, an optional phosphorus source, an optional boron source, a pH adjusting agent and a surfactant.

Cobalt sources usually have a cobalt concentration in the range from about 50 mM to about 250 mM. Cobalt sources include cobalt chlorides (e.g., COCl₂.6H₂O), cobalt sulfates (e.g., COSO₄.7H₂O) and combinations thereof. In one embodiment, CoCl₂.6H₂O is added to the CoW solution with a concentration in the range from about 1 g/L to about 100 g/L, preferably from about 15 g/L to about 35 g/L. In another embodiment, COSO₄.7H₂O is added to the CoW solution with a concentration in the range from about 1 g/L to about 100 g/L, preferably from about 15 g/L to about 35 g/L.

Tungsten sources usually have a tungsten concentration in the range from about 10 mM to about 100 mM. Tungsten sources may include CaWO₄, (NH₄)₂WO₄, H₂WO₄, other WO₄²⁻ sources, combinations thereof. In one embodiment, (NH₄)₂WO₄ is added to the CoW solution with a concentration in the range from about 1 g/L to about 50 g/L, preferably from about 5 g/L to about 15 g/L.

CoW alloys generally include elemental additives, such as phosphorus, boron and/or combinations thereof. These elemental additives are derived from CoW solutions as phosphorus sources and/or boron sources from the reducing agents. A phosphorus source has a concentration in the range from about 50 mM to about 500 mM, preferably from about 75 mM to about 225 mM. Phosphorus sources include H₃PO₂, salts thereof, derivatives thereof and combinations thereof. One such phosphorus source is usually 50% hypophosphorous acid (H₃PO₂). In one embodiment, H₃PO₂ is in the CoW solution with a concentration in the range from about 1 g/L to about 50 g/L, preferably from about 5 g/L to about 15 g/L. A boron source has a concentration in the range from about 50 mM to about 500 mM, preferably from about 85 mM to about 260 mM. One such boron source is usually dimethylamine-borane complex ((CH₃)₂NH.BH₃, DMAB). In one embodiment, DMAB is in the CoW solution with a concentration in the range from about 1 g/L to about 50 g/L, preferably from about 5 g/L to about 15 g/L.

Complexing agents may be added to the CoW solution with a concentration from about 50 mM to about 500 mM, preferably from about 150 mM to about 380 mM. Complexing agents include carboxylic acids, such as EDTA and citric acid. In one embodiment, citric acid is in the CoW solution with a concentration in the range from about 30 g/L to about 70 g/L, preferably at about 50 g/L. Buffering compounds are added to the CoW solution with a concentration from about 10 mM to about 200 mM, preferably from about 30 mM to about 80 mM. In one embodiment, a buffering compound is boric acid (H₃BO₃) with a concentration in the range from about 0.5 g/L to about 10 g/L, preferably from about 2 g/L to about 5 g/L in a CoW solution. Generally, pH adjusting agents, such as bases and acids, are added to adjust the pH of the CoW solution. Bases are used in increase the pH of the CoW solution and include hydroxides, amines and hydrides, such as TMAH, ammonium hydroxide (NH₄OH), dimethylamine ((CH₃)₂NH) and combinations thereof. Bases are used to maintain the pH in a range from about 7 to about 12, preferably from about 8 to about 12. In one embodiment, NH₄OH is in the CoW solution with a concentration in the range from about 5 g/L to about 100 g/L, preferably from about 20 g/L to about 25 g/L. In another embodiment, 25% TMAH is in the CoW solution with a concentration in the range from about 5 g/L to about 100 g/L, preferably from about 20 g/L to about 25 g/L. Acids are used to decrease the pH and include hydrochloric acid, sulfuric acid, acetic acid, nitric acid, hydrofluoric acid and combinations thereof. Optionally, antifungal compounds or antibacterial compounds are added to the CoW solution including metal salts (e.g., CuSO₄) or organic compounds, such as benzoic acid derivatives, for example, methyl 4-hydroxy benzoic acid.

During step 110, the activation layer 14 is exposed to a complexing agent solution. Various compositions of complexing agent solutions are described in step 102. The complexing agent solution further cleans the substrate surface and removes remaining contaminants from any of the early processes. Complexing agents are useful to chelate with metal ions, such as tungsten, cobalt, calcium, copper and/or palladium; Generally, the substrate surface is exposed to the complexing agent solution for a period from about 10 seconds to about 120 seconds, preferably from about 30 seconds to about 60 seconds.

Following exposure of the substrate to the complexing agent solution, the substrate surface is rinsed. The rinse step includes washing any remaining complexing solution and/or contaminants from the surface with deionized water. The substrate will be rinsed for a period from about 5 seconds to about 120 seconds, preferably for about 30 seconds.

The substrate is dried and annealed during step 112. The substrate is placed into an annealing chamber and heated to a temperature in the range from about 100° C. to about 500° C., preferably from about 150° C. to about 250° C. In one embodiment, the atmosphere includes a process gas, such as H₂, N₂, Ar, forming gas and combinations thereof, preferably a 10% mixture of H₂ in N₂. The wafer is maintained in this environment for a period in a range from about 5 seconds to about 60 seconds, preferably from about 10 seconds to about 15 seconds. Subsequently, in the same temperature range, the chamber is evacuated to a pressure in a range from about 10⁻⁷ Torr to about 10⁻³ Torr for about 1 minute and the wafer is annealed for a period in a range from about 30 seconds to about 5 minutes, preferably from about 1 minute to about 2 minutes.

The processes described herein may be performed in an apparatus suitable for performing an electroless deposition process (EDP). A suitable apparatus includes the SLIMCELLTM processing platform that is available from Applied Materials, Inc., located in Santa Clara, Calif. The SLIMCELLTM platform, for example, includes an integrated processing chamber capable of depositing a conductive material by an electroless process, such as an EDP cell, which is available from Applied Materials, Inc., located in Santa Clara, Calif. The SLIMCELLTM platform generally includes one or more EDP cells as well as one or more pre-deposition or post-deposition cell, such as spin-rinse-dry (SRD) cells, etch chambers, or annealing chambers. A further description of EDP platforms and EDP cells may be found in the commonly assigned U.S. Provisional Patent Application Ser. No. 60/511,236, entitled, “Apparatus for Electroless Deposition,” filed on Oct. 15, 2003, U.S. Provisional Patent Application Ser. No. 60/539,491, entitled, “Apparatus for Electroless Deposition of Metals on Semiconductor Wafers,” filed on Jan. 26, 2004, U.S. Provisional Patent Application Ser. No. 60/575,553, entitled, “Face Up Electroless Plating Cell,” filed on May 28, 2004, and U.S. Provisional Patent Application Ser. No. 60/575,558, entitled, “Face Down Electroless Plating Cell,” filed on May 28, 2004, which are each incorporated by reference to the extent not inconsistent with the claimed aspects and description herein.

An integrated activation-electroless system includes manipulating the process parameters by the chamber control system. A controlled environment, produced in the chamber, helps prevent corrosion by limiting oxygen contamination from the ambient air. The system may be flushed with a purge gas to reduce concentrations of contaminant gases, such as oxygen. Purge gases include N₂, H₂, N₂H₂, Ar, He or combinations thereof. The purge gas may be directed at the substrate surface or bubbled through the solutions. Solutions may be deoxygenated by passing a purge gas stream through the solution and/or applying sonication techniques, such as megasonic or ultrasonic treatment. The solutions may also be heated prior to deposition to help deoxygenate. Generally, the solution is heated to a temperature in the range from about 60° C. to about 95° C. to initiate deposition, while oxygen is removed as a consequence.

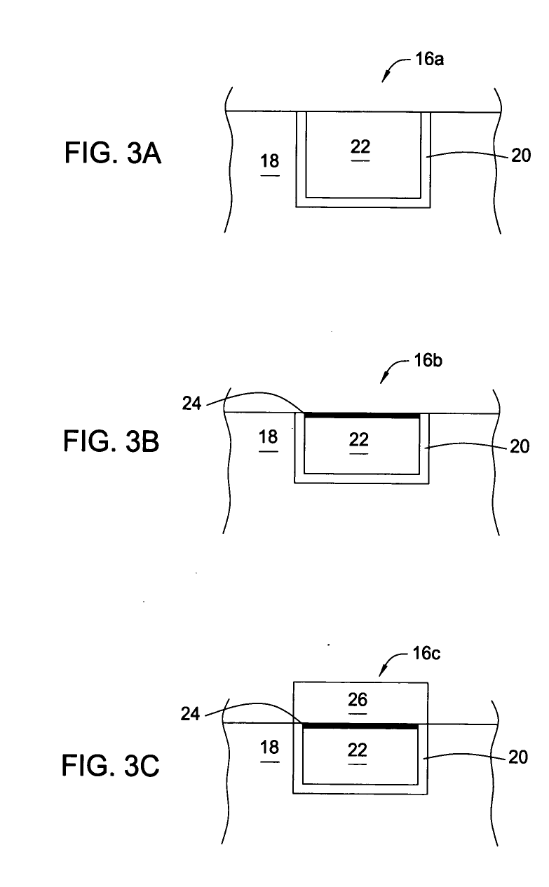

In another embodiment of the invention, an activation-alloy is formed by ion implantation of elements (e.g., metals) into the surface of a conductive layer. The ion implantation converts the surface of the conductive material to an activation-alloy. FIG. 3A shows a cross-sectional view of an interconnect 16a containing a conductive material 22 disposed into low-k material 18 on a substrate surface. Conductive material 22 includes metals, such as copper, aluminum, tungsten, various alloys of the aforementioned metals and combinations thereof. Preferably conductive material 22 is copper or a copper alloy. The conductive material 22 is generally deposited by a deposition process, such as electroplating, electroless plating, PVD, CVD, ALD and/or combinations thereof.

As depicted in FIG. 3A, conductive material 22 may have already been polished or leveled, such as by a CMP technique. A barrier layer 20 separates low-k material 18 from the conductive material 22. Low-k material 18 may include features, such as electrodes or interconnects, throughout the layer (not shown). Barrier layer 20 is usually a material that includes tantalum, tantalum nitride, tantalum silicon nitride, titanium, titanium nitride, tungsten nitride, silicon nitride and combinations thereof. Barrier layer 20 is usually deposited with a PVD, ALD or CVD technique.

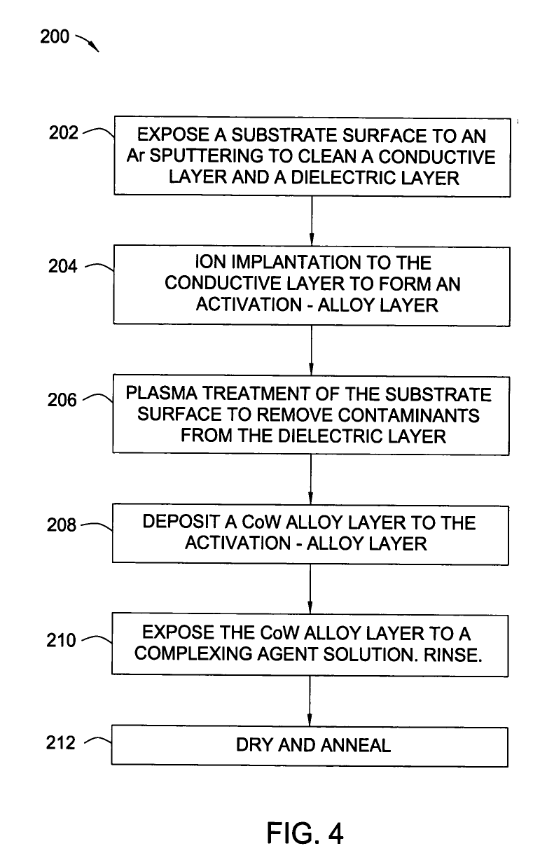

FIGS. 3A-3C depict cross-sectional views of interconnect 16 resulting from steps taken during a process 200 shown in FIG. 4, a flow chart illustrating steps taken during one embodiment of the invention. The substrate is placed into a ion implant chamber, such as the Quantum™ series implanter, available from Applied Material Inc., located in Santa Clara, Calif. During step 202, the substrate is exposed to an argon sputtering to clean the conductive material and the dielectric layer. The argon sputtering removes oxides, residues and/or contaminates left from a previous fabrication process (e.g., CMP). Contaminants include oxides, copper oxides, copper-organic complexes, silicon oxides, BTA, resist, polymeric residue, derivatives thereof and combinations thereof. The exposure time of the argon sputtering will range from about 5 second to about 120 seconds, preferably from about 10 seconds to about 30 seconds and more preferably at about 20 seconds. The Ar-sputtering treats the exposed surface and removes contaminates from conductive material 22, barrier layer 20 and low-k material 18.

Once the surface of the substrate is cleaned, ion implantation is commenced during step 204. Ion implantation includes depositing ions via a plasma into the surface of the substrate, namely the conductive material 22. The plasma is formed with an output setting from about 10 keV to about 200 keV. As the ion implant the conductive material 22, an activation-alloy layer 24 is created by the increased concentration of the ions being implanted into the conductive material 22. For example, when conductive material 22 is copper and the implanting ions are cobalt, then a CoCu alloy is formed as an activation-alloy layer 24. Generally, the ion implantation may embed ions forming activation-alloy layer with a concentration from about 10¹⁶ atoms/cm³ to about 10¹⁴ atoms/cm³ within the conductive material 22. The activation-alloy layer 24, formed by an ion implantation process, may have a thickness as deep as the ion implantation technique permits the embedding ions into the conductive material 22; generally, from about a single atomic layer to about 50 Å.

A variety of metals and elements may be formed by the ion implantation technique utilizing sources of the elements Ru, Rh, Ir, Pt, Pd, Ni, Ag, Au, Cu, Re, Mo, Co, alloys thereof and combinations thereof. Specific compounds or alloys formed by ion implantation may include PdCu, PdCoCu, PdNiCu, CoCu, PtCu, IrCu, RhCu, RuCu, CoRh, CoNiCu, NiCu, CoCuIr, PdCuIr, PdCoIr, PdNiIr, CoNiIr, NiCuIr, RhCo and derivatives thereof. For example, a palladium source may be ionized and implanted into a copper layer to produce a PdCu activation-alloy layer. In another example, a palladium-cobalt alloy source may be ionized and implanted into a copper layer to produce a PdCoCu activation-alloy layer. In another example, a ruthenium source may be ionized and implanted into a copper layer to produce a RuCu activation-alloy layer. In another example, a cobalt source may be ionized and implanted into a copper layer to produce a CoCu activation-alloy layer. In another example, a cobalt-iridium source may be ionized and implanted into a copper layer to produce a ColrCu activation-alloy layer.

The activation-alloys may also contain additive elements, such as boron, phosphorus, carbon, sulfur, nitrogen and combinations thereof. Examples of PdCu activation-alloys include PdCuS, PdCuP, PdCuB, PdCuSP, PdCuSB, PdCuPB and PdCuSPB. Others acitivation alloys of CoCu include CoCuS, CoCuP, CoCuB, CoCuSP, CoCuSB, CoCuPB and CoCuSPB. For example, a PdS source may be ionized and implanted into a copper layer to produce a PdCuS activation-alloy layer. In another example, a PdB source may be ionized and implanted into a copper layer to produce a PdCuB activation-alloy layer. In another example, a COWPB source may be ionized and implanted into a copper layer to produce a CoWCuPB activation-alloy layer.

Once the activation-alloy layer 24 is formed on conductive material 22 within interconnect 16b, the substrate surface is cleaned by a plasma treatment in step 206. The plasma treatment removes contaminants from the substrate surface, such as residues of the activation-alloy from the low-k material 18. Contaminants on low-k material 18 may cause problems, such as electrical shorts, in the interconnect 16.

In FIG. 3C, a CoW alloy layer 26 is deposited to the activation-alloy layer 24 during step 208. The CoW alloy layer is deposited by the process described in step 108. Step 210 cleans the substrate surface with a complexing solution according to the process described in step 110. Step 212 dries and anneals the substrate according to the process described in step 112. The final interconnect 6c is formed.

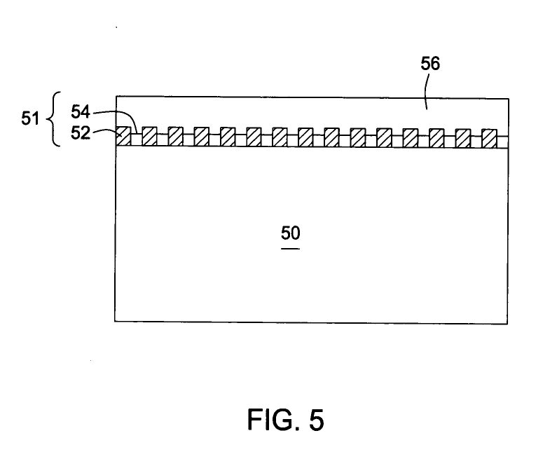

In FIG. 5, an activation-alloy layer 51 comprises islands 52 of an alloy containing at least two metals (e.g., PdCu-alloy) and islands 54 of at least another element (e.g., sulfur). The activation alloy is displaced on a conductive material 50 (e.g., copper). Islands 52 and 54 are formed by over lapping a discontinuous layer of an alloy with a discontinuous layer of at least another element. Therefore, PdCuS satellites or islands of PdCu-alloys and sulfur are formed across the conductive material 50. A CoW alloy layer 56 is deposited over the activation-alloy 51. In one example, the activation-alloy layer 51 may have a thickness from a single atomic layer to about 100 Å, preferably from about 5 Å to about 50 Å, while the CoW alloy layer 56 may have a thickness about 150 Å or less.

In another embodiment of the invention, an activation-alloy is deposited by an ALD process. Generally, ALD processes sequential pulse precursors and/or reagents to deposit a film. For example, an ALD process may pulse a metal source, a reducing agent, a second metal source and the reducing agent to deposit a binary activation-alloy film. ALD processes are further described in commonly assigned U.S. Pat. Nos. 6,551,929 and 6,607,975, which are incorporated by reference herein to the extent not inconsistent with the claimed aspects and description herein. Apparatuses useful to conduct ALD processes, such as the Endura™ process platform equipped with an ALD chamber available from Applied Materials Inc., located in Santa, Clara Calif. An ALD chamber useful for the invention is more fully described in commonly assigned U.S. application Ser. No. 10/032,284, entitled, “Gas Delivery Apparatus and Method for Atomic Layer Deposition,” filed Dec. 21, 2001, published as United States Patent Publication Number 20030079686, which is incorporated by reference herein to the extent not inconsistent with the claimed aspects and description herein.

In one example, an activation-alloy, such as a PdCu alloy, is deposited to a conductive layer. A copper precursor is pulsed into the process chamber and chemisorbs to the substrate surface. A reducing agent is pulsed into the chamber and reacts with the chemisorbed copper precursor layer. A palladium precursor is pulsed into the chamber and chemisorbs to the substrate surface. The reducing agent is pulsed into the chamber and reacts with the chemisorbed palladium precursor layer. This cycle is repeated to grow a PdCu alloy layer. In one example, the palladium precursor and reducing agent half cycle is repeated numerous times (e.g., 10) for each copper precursor and reducing agent half cycle. Therefore, a desired Pd:Cu ratio (e.g., 10) may be incorporated into the PdCu alloy layer. In another example, an activation alloy has a copper concentration in a range from about 10 ppm to about 1%, preferably from about 50 ppm to about 1,000 ppm.

In another example, a pulse of gas containing a copper precursor and a palladium precursor is delivered and chemisorbed to the substrate surface. A pulse of reducing agent is delivered to the substrate and reacts with the chemisorbed layer to produce a PdCu alloy layer. This cycle is repeated to grow a PdCu alloy layer. A ratio of copper precursor and palladium precursor may be adjusted to incorporate a desired Pd:Cu ratio, for example, about 10.

During the ALD processes, a purge gas may be pulsed between each of the precursors and/or reagents pulses. Alternatively, a stream of purge gas (e.g., carrier gas) may flow continuously through the chamber while the precursors and/or reagents are pulsed into the purge gas. A purge gas or carrier gas may include N₂, Ar, H₂, He, forming gas and combinations thereof. The activation-alloy is deposited with an ALD process to a thickness from about an atomic layer to about 50 Å.

Copper precursors useful in the invention include copper(I)chloride (CuCl), copper(I)bromide (CuBr), copper(I)iodide (CuI), bis(6,6,7,7,8,8,8-heptafluoro-2,2-dimethyl-3,5-octanedionato)copper(II) (Cu(FOD)₂), bis(2,2,6,6-tetramethyl-3,5-heptanedionato)copper(II) (Cu(thd)₂), copper(I)acetylacetonate (Cu(CH₃COCHCOCH₃)₂ (Cu(acac)₂), copper(II)trifluoroacetylacetonate (Cu(CF₃COCHCOCH₃)₂), copper(II)hexafluoroacetylacetonate (Cu(CF₃COCHCOCF₃)₂, Cu(hfac)₂), hexafluoroacetylacetonatocopper(I)trimethylphosphine complex (Cu(CF₃ COCHCOCF₃)P(CH₃)₃), cyclopentadienylcopper(I)triethylphosphine ((C₅H₅)Cu: P(C₂H₅)₃), ethylcyclopentadienylcopper triphenylphosphine complex ((C₂H₅C₅H₄)Cu: P(C₆H₅)₃), hexafluoroacetylacetonatocopper(I)triethylphosphine complex ((C₅HF₆O₂)Cu:P(C₂H₅)₃), hexafluoroacetylacetonatocopper(1)₂-butyne complex ((C₅HF₆O₂)Cu:CH₃C≡CCH₃), hexafluoroacetylacetonatocopper(I)1,5-cyclooctadiene complex ((C₅HF₆O₂)Cu:C₈H₁₂), hexafluoropentanedionatocopper(I)vinyltrimethylsilane complex ((hfac)Cu(VTMS)) and copper nitrate (Cu(NO₃)₂). Other copper precursors include copper β-diketonate complexes and copper β-diketiminate complexes, as described in commonly assigned U.S. Pat. No. 6,620,956, which is incorporated by reference herein to the extent not inconsistent with the claimed aspects and description herein. Palladium precursors useful in the invention include bis(tri-tertbutylphosphine)palladium ((tBu₃P)₂Pd), palladium(II)acetate ((CH₃CO₂)₂Pd), palladium(II)acetylacetonate ((C₅H₇O₂)₂Pd, palladium(II)hexafluoroacetylacetonate (Pd(CF₃COCHCOCF₃)₂, Pd(hfac)₂), Pd(acac)₂), bis(1,1,1,5,5,5-hexafluoro-2,4-pentanedionato)palladium (Pd(CF₃COCHCOCF₃)₂) and Pd(thd)₂. Reducing agents useful in the invention include borane complexes, diborane, silane, disilane, hydrogen, atomic hydrogen, ammonia, derivatives thereof and combinations thereof. Elemental additives may be added, such as tungsten by using WF₆ as a precursor or phosphorus by using PH₃ or P(CH₃)₃ as a precursor.

In another example, an activation-alloy, such as a RuCu alloy or a Ru metal, is deposited to a conductive layer. A copper precursor is pulsed into the process chamber and chemisorbs to the substrate surface. A reducing agent is pulsed into the chamber and reacts with the chemisorbed copper precursor layer. A ruthenium precursor is pulsed into the chamber and chemisorbs to the substrate surface. The reducing agent is pulsed into the chamber and reacts with the chemisorbed ruthenium precursor layer. This cycle is repeated to grow a RuCu alloy layer. In one example, the ruthenium precursor and reducing agent half cycle is repeated numerous times (e.g., 10) for each copper precursor and reducing agent half cycle. Therefore, a desired Ru:Cu ratio (e.g., 10) may be incorporated into the RuCu alloy layer. In another example, an activation alloy has a copper concentration in a range from about 10 ppm to about 1%, preferably from about 50 ppm to about 1,000 ppm.

In another example, a pulse of gas containing a copper precursor and a ruthenium precursor is delivered and chemisorbed to the substrate surface. A pulse of reducing agent is delivered to the substrate and reacts with the chemisorbed layer to produce a RuCu alloy layer. This cycle is repeated to grow a RuCu alloy layer. A ratio of copper precursor and ruthenium precursor may be adjusted to incorporate a desired Ru:Cu ratio, for example, about 10.

During the ALD processes, a purge gas may be pulsed between each of the precursors and/or reagents pulses. Alternatively, a stream of purge gas (e.g., carrier gas) may flow continuously through the chamber while the precursors and/or reagents are pulsed into the purge gas. A purge gas or carrier gas may include N₂, Ar, H₂, He, forming gas and combinations thereof. The activation-alloy is deposited with an ALD process to a thickness from about an atomic layer to about 50 Å.

In another example, a ruthenium metal layer is deposited as an activation layer by an ALD process. The ruthenium metal layer may be deposited by an ALD process more fully described in commonly assigned U.S. application Ser. No. 10/881,230, entitled, “Ruthenium Layer Formation for Copper Film Deposition,” filed Mar. 26, 2004, which is incorporated by reference herein to the extent not inconsistent with the claimed aspects and description herein.

Embodiments of the present invention include ruthenium-containing compounds or precursors that include bis(ethylcyclopentadienyl)ruthenium, bis(cyclopentadienyl)ruthenium and bis(pentamethylcyclopentadienyl)ruthenium or include ruthenium and at least one open chain dienyl ligand, such as CH₂CRCHCRCH₂, where R is independently an alkyl group or hydrogen. In one embodiment, the ruthenium-containing compound has two open-chain dienyl ligands, such as pentadienyl or heptadienyl. A bis(pentadienyl)ruthenium compound has a generic chemical formula (CH₂CRCHCRCH₂)₂Ru, where R is independently an alkyl group or hydrogen. Usually, R is independently hydrogen, methyl, ethyl, propyl or butyl. Therefore, ruthenium-containing compounds may include bis(dialkylpentadienyl)ruthenium compounds, bis(alkylpentadienyl)ruthenium compounds, bis(pentadienyl)ruthenium compounds and combinations thereof. Examples of ruthenium-containing compounds include bis(2,4-dimethylpentadienyl)ruthenium, bis(2,4-diethylpentadienyl)ruthenium, bis(2,4-diisopropylpentadienyl)ruthenium, bis(2,4-ditertbutylpentadienyl)ruthenium, bis(methylpentadienyl)ruthenium, bis(ethylpentadienyl)ruthenium, bis(isopropylpentadienyl)ruthenium, bis(tertbutylpentadienyl)ruthenium, derivatives thereof and combinations thereof. In some embodiments, other ruthenium-containing compounds include tris(2,2,6,6-tetramethyl-3,5-heptanedionato)ruthenium, dicarbonyl pentadienyl ruthenium, ruthenium acetyl acetonate, (2,4-dimethylpentadienyl)ruthenium(cyclopentadienyl), bis(2,2,6,6-tetramethyl-3,5-heptanedionato)ruthenium(1,5-cyclooctadiene), (2,4-dimethylpentadienyl)ruthenium(methylcyclopentadienyl), (1,5-cyclooctadiene)ruthenium(cyclopentadienyl), (1,5-cyclooctadiene)ruthenium(methylcyclopentadienyl), (1,5-cyclooctadiene)ruthenium(ethylcyclopentadienyl), (2,4-dimethylpentadienyl)ruthenium(ethylcyclopentadienyl), (2,4-dimethylpentadienyl)ruthenium(isopropylcyclopentadienyl), bis(N,N-dimethyl 1,3-tetramethyl diiminato)ruthenium(1,5-cyclooctadiene), bis(N,N-dimethyl 1,3-dimethyl diiminato)ruthenium(1,5-cyclooctadiene), bis(allyl)ruthenium(1,5-cyclooctadiene), (η⁶-C₆H₆)ruthenium(1,3-cyclohexadiene), bis(1,1-dimethyl-2-aminoethoxylato)ruthenium(1,5-cyclooctadiene), bis(1,1-dimethyl-2-aminoethylaminato)ruthenium(1,5-cyclooctadiene), derivatives thereof and combinations thereof.

Suitable reducing gases to react with ruthenium-containing compounds may include traditional reductants, for example, hydrogen (e.g., H₂ or atomic-H), ammonia (NH₃), silane (SiH₄), disilane (Si₂H₆), trisilane (Si₃H₈), tetrasilane (Si₄H₁o), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triborane, tetraborane, pentaborane, triethylborane (Et₃B), derivatives thereof and combinations thereof.

In other embodiments, especially when the ruthenium-containing compounds has an opened-chain dienyl ligand the reducing gas may include oxygen-containing gases used as a reductant, such as oxygen (e.g., O₂), nitrous oxide (N₂O), nitric oxide (NO), nitrogen dioxide (NO₂), derivatives thereof and combinations thereof. Furthermore, the traditional reductants may be combined with the oxygen-containing reductants to form a reducing gas. Oxygen-containing gases that are used in embodiments of the present invention are traditionally used in the chemical art as an oxidant. However, ligands on an organometallic compound containing a noble metal (e.g., Ru) are usually more susceptible to the oxygen-containing reductants than the noble metal. Therefore, the ligand is generally oxidized from the metal center while the metal ion is reduced to form the elemental metal. In one embodiment, the reducing gas is air containing ambient oxygen as the reductant. The air may be dried over sieves to reduce ambient water.

### EXAMPLES

### Example 1

An activation-alloy solution includes the following concentration: CuSO₄.5H₂O from about 15 g to about 30 g; PdSO₄.7H₂O from about 15 g to about 100 g; citric acid from about 50 g to about 80 g; tartaric acid from about 50 g to about 80 g; DMAB from about 5 g to about 20 g; RE-610 from about 50 ppm to about 500 ppm; NH₄OH to a pH on the range from about 7 to about 12, preferably from about 9 to about 12; and deionized water to form about 1 L.

### Example 2

An activation-alloy solution includes the following concentration: CuSO₄.5H₂O from about 15 g to about 30 g; PdSO₄.7H₂O from about 15 g to about 100 g; glyoxylic acid from about 50 g to about 80 g; tartaric acid from about 50 g to about 80 g; RE-610 from about 50 ppm to about 500 ppm; TMAH to a pH on the range from about 7 to about 12, preferably from about 9 to about 12; and deionized water to form about 1 L.

### Example 3

An activation-alloy solution includes the following concentration: CuSO₄.5H₂O from about 15 g to about 30 g; PdSO₄.7H₂O from about 15 g to about 100 g; citric acid from about 50 g to about 80 g; H₃PO₂ from about 5 g to about 40 g; RE-610 from about 50 ppm to about 500 ppm; NH₄OH to a pH on the range from about 7 to about 12, preferably from about 9 to about 12; and deionized water to form about 1 L.

### Example 4

An activation-alloy solution includes the following concentration: CuSO₄.5H₂O from about 15 g to about 30 g; PdSO₄.7H₂O from about 15 g to about 100 g; EDTA from about 50 g to about 80 g; glyoxylic acid from about 50 g to about 80 g; DMAB from about 5 g to about 20 g; RE-610 from about 50 ppm to about 500 ppm; TMAH to a pH on the range from about 7 to about 12, preferably from about 9 to about 12; and deionized water to form about 1 L.

### Example 5

An activation-alloy solution includes the following concentration: CuSO₄.5H₂O from about 15 g to about 30 g; PdSO₄.7H₂O from about 15 g to about 100 g; (NH₄)₂WO₄ from about 15 g to about 30 g; EDA from about 50 g to about 80 g; glyoxylic acid from about 50 g to about 80 g; DMAB from about 5 g to about 20 g; RE-610 from about 50 ppm to about 500 ppm; TMAH to a pH on the range from about 7 to about 12, preferably from about 9 to about 12; and deionized water to form about 1 L.

### Example 6

An activation-alloy solution includes the following concentration: CuSO₄.5H₂O from about 15 g to about 30 g; COSO_{40.7}H₂O from about 15 g to about 30 g; citric acid from about 50 g to about 80 g; tartaric acid from about 50 g to about 80 g; DMAB from about 5 g to about 20 g; RE-610 from about 50 ppm to about 500 ppm; NH₄OH to a pH on the range from about 7 to about 12, preferably from about 9 to about 12; and deionized water to form about 1 L.

### Example 7

An activation-alloy solution includes the following concentration: CuSO₄.5H₂O from about 15 g to about 30 g; CoSO₄.7H₂O from about 15 g to about 30 g; glyoxylic acid from about 50 g to about 80 g; tartaric acid from about 50 g to about 80 g; RE-610 from about 50 ppm to about 500 ppm; TMAH to a pH on the range from about 7 to about 12, preferably from about 9 to about 12; and deionized water to form about 1 L.

### Example 8

An activation-alloy solution includes the following concentration: CuSO₄.5H₂O from about 15 g to about 30 g; CoSO₄.7H₂O from about 15 g to about 30 g; citric acid from about 50 g to about 80 g; H₃PO₂ from about 5 g to about 40 g; RE-610 from about 50 ppm to about 500 ppm; NH₄OH to a pH on the range from about 7 to about 12, preferably from about 9 to about 12; and deionized water to form about 1 L.

### Example 9

An activation-alloy solution includes the following concentration: CuSO₄.5H₂O from about 15 g to about 30 g; COSO₄.7H₂O from about 15 g to about 30 g; EDTA from about 50 g to about 80 g; glyoxylic acid from about 50 g to about 80 g; DMAB from about 5 g to about 20 g; RE-610 from about 50 ppm to about 500 ppm; TMAH to a pH on the range from about 7 to about 12, preferably from about 9 to about 12; and deionized water to form about 1 L.

While the foregoing is directed to embodiments of the present invention, other and further embodiments of the invention may be devised without departing from the basic scope thereof, and the scope thereof is determined by the claims that follow.

1. A method for depositing a capping layer for a semiconductor device, comprising:
exposing a conductive layer on a substrate surface to an activation-alloy solution;
forming an activation-alloy layer on the conductive layer using the activation-alloy solution; and
depositing the capping layer on the activation-alloy layer using an electroless deposition solution.

2. The method of claim 1, wherein the capping layer is a CoW alloy comprising cobalt and at least one element selected from the group consisting of tungsten, boron, phosphorus and combinations thereof.

3. The method of claim 2, wherein the conductive layer comprises copper.

4. The method of claim 3, wherein the activation-alloy solution comprises a copper source and a secondary metal source.

5. The method of claim 4, wherein the copper source is selected from the group consisting of copper sulfate, copper chloride, copper acetylacetonate, copper acetate, derivatives thereof, hydrates thereof and combinations thereof.

6. The method of claim 5, wherein the secondary metal source is selected from the group consisting of cobalt sulfate, cobalt chloride, cobalt acetylacetonate, cobalt acetate, palladium chloride, palladium sulfate, palladium acetate, ammonium tungstate, tungstic acid, calcium tungstate, derivatives thereof, hydrates thereof and combinations thereof.

7. The method of claim 6, further comprising a complexing agent selected from the group consisting of carboxylic acids, citric acid, citrates, acetates, tartaric acid, EDTA, EDA, derivatives thereof, salts thereof and combinations thereof.

8. The method of claim 5, further comprising an acid selected from the group consisting of hydrochloric acid, hydrofluoric acid, sulfuric acid, a phosphorous-containing acid, derivatives thereof, salts thereof and combinations thereof.

9. The method of claim 7, further comprising a base selected from the group consisting of TMAH, NH₄OH, amines, hydroxides, derivatives thereof and combinations thereof.

10. The method of claim 9, further comprising a surfactant.

11. The method of claim 7, further comprising a reductant selected from the group consisting of borane complexes, DMAB, borane, hydrazine, glyoxylic acid, hypophosphorous acid, derivatives thereof, salts thereof and combinations thereof.

12. The method of claim 4, further comprising a sulfur source selected from the group consisting of sulfates, disulfides, thiols, mercaptans, derivatives thereof and combinations thereof.

13. The method of claim 4, wherein the activation-alloy layer comprises copper and at least one element selected from the group consisting of cobalt, palladium, and combinations thereof.

14. The method of claim 13, further comprising at least another element selected from the group consisting of tungsten, boron, phosphorus, sulfur and combinations thereof.

15. The method of claim 13, wherein the activation-alloy layer has a thickness in a range from about one atomic layer to about 500 Å.

16. The method of claim 15, wherein the activation-alloy layer has a copper concentration range from about 50 ppm to about 1,000 ppm.

17. A method for depositing a capping layer for a semiconductor device, comprising:
forming an activation-alloy layer on a copper layer disposed on a substrate surface; and
exposing the activation-alloy layer to a capping solution to deposit the capping layer on the activation-alloy layer.

18. The method of claim 17, wherein the activation-alloy comprises at least two elements selected from the group consisting of palladium, copper, cobalt, nickel, tungsten, molybdenum, platinum, rhodium, ruthenium and combinations thereof.

19. The method of claim 18, further comprising at least one element selected from the group consisting of boron, phosphorus, sulfur and combinations thereof.

20. The method of claim 18, wherein the activation-alloy layer is formed by an ion implantation process.

21. The method of claim 20, wherein the activation-alloy comprises a copper-cobalt alloy.

22. The method of claim 21, wherein the copper-cobalt alloy comprises an atomic ratio of about 10:1 for Cu:Co.

23. The method of claim 22, wherein the copper-cobalt alloy is deposited as a continuous layer.

24. The method of claim 18, wherein the activation-alloy layer is formed by an electroless deposition process.

25. The method of claim 24, wherein the activation-alloy comprises a palladium-copper alloy.

26. The method of claim 25, wherein the palladium-copper alloy comprises an atomic ratio of about 15:1 for Pd:Cu.

27. The method of claim 26, wherein the palladium-copper alloy is deposited as a discontinuous layer.

28. The method of claim 18, wherein the activation-alloy layer is formed by an ALD process.

29. The method of claim 28, wherein the activation-alloy comprises a palladium-copper alloy.

30. The method of claim 29, wherein the palladium-copper alloy comprises an atomic ratio of about 15:1 for Pd:Cu.

31. The method of claim 29, wherein the activation alloy layer has a copper concentration range from about 50 ppm to about 1,000 ppm.

32. The method of claim 29, wherein the ALD process includes a palladium precursor and a copper precursor.

33. The method of claim 32, wherein the palladium precursor is selected from the group consisting of (tBu₃P)₂Pd, (CH₃CO₂)₂Pd), Pd(acac)₂, Pd(hfac)₂, Pd(thd)₂ and derivatives thereof.

34. The method of claim 32, wherein the copper precursor is selected from the group consisting of CuCl, CuBr, CuI, Cu(thd)₂, Cu(acac)₂, Cu(hfac)₂, (C₅H₅)Cu:P(C₂H₅)₃, (C₂H₅C₅H₄)Cu:P(C₆H₅)₃, (C₅H F₆O₂)Cu:P(C₂H₅)₃, (C₅HF₆O₂)Cu:CH₃C≡CCH₃, ((C₅H F₆O₂)Cu:C₈H 12), (hfac)Cu(VTMS) and derivatives thereof.

35. The method of claim 17, wherein the capping layer is a CoW alloy comprising cobalt and at least one element selected from the group consisting of tungsten, boron, phosphorus and derivatives thereof.

36. A composition of a deposition solution for depositing an activation-alloy comprising:
a copper source in a range from about 10 mM to about 100 mM;
a cobalt source in a range from about 50 mM to about 500 mM;
a complexing agent in a range from about 100 mM to about 700 mM; and
a pH adjusting agent with a concentration to provide the deposition solution with a pH in a range from about 7 to about 12.

37. The composition of claim 36, wherein the copper source is selected from the group consisting of copper sulfate, copper chloride, copper acetylacetonate, copper acetate, derivatives thereof, hydrates thereof and combinations thereof.

38. The composition of claim 37, wherein the cobalt source is selected from the group consisting of cobalt sulfate, cobalt chloride, cobalt acetylacetonate, cobalt acetate, derivatives thereof, hydrates thereof and combinations thereof.

39. The composition of claim 38, further comprising a phosphorus-containing acid in a range from about 50 mM to about 500 mM.

40. The composition of claim 38, further comprising at least one reductant in a range from about 50 mM to about 500 mM.

41. The composition of claim 40, wherein the at least one reductant is selected from the group consisting of borane complexes, DMAB, borane, hydrazine, glyoxylic acid, hypophosphorous acid, derivatives thereof, salts thereof and combinations thereof.

42. The composition of claim 38, wherein the complexing agent is selected from the group consisting of carboxylic acids, citric acid, citrates, acetates, tartaric acid, EDTA, EDA, derivatives thereof, salts thereof and combinations thereof.

43. The composition of claim 38, wherein the pH adjusting agent is selected from the group consisting of TMAH, NH₄OH, amines, hydroxides, derivatives thereof and combinations thereof.

44. The composition of claim 38, further comprising a sulfur source selected from the group consisting of sulfates, disulfides, thiols, mercaptans, derivatives thereof and combinations thereof.

45. A composition of a deposition solution for depositing an activation-alloy comprising:
a copper source in a range from about 10 mM to about 100 mM;
a palladium source in a range from about 50 mM to about 500 mM;
a complexing agent in a range from about 100 mM to about 700 mM; and
a pH adjusting agent in a range from about 50 mM to about 500 mM.

46. The composition of claim 45, wherein the copper source is selected from the group consisting of copper sulfate, copper chloride, copper acetylacetonate, copper acetate, derivatives thereof, hydrates thereof and combinations thereof.

47. The composition of claim 46, wherein the palladium source is selected from the group consisting of palladium chloride, palladium sulfate, palladium acetate, derivatives thereof, hydrates thereof and combinations thereof.

48. The composition of claim 47, further comprising a phosphorus-containing acid in a range from about 50 mM to about 500 mM.

49. The composition of claim 47, further comprising at least one reductant in a range from about 50 mM to about 500 mM.

50. The composition of claim 49, wherein the at least one reductant is selected from the group consisting of borane complexes, DMAB, borane, hydrazine, glyoxylic acid, hypophosphorous acid, derivatives thereof, salts thereof and combinations thereof.

51. The composition of claim 47, wherein the complexing agent is selected from the group consisting of carboxylic acids, citric acid, citrates, acetates, tartaric acid, EDTA, EDA, derivatives thereof, salts thereof and combinations thereof.

52. The composition of claim 47, wherein the pH adjusting agent is selected from the group consisting of TMAH, NH₄OH, amines, hydroxides, derivatives thereof and combinations thereof.

53. The composition of claim 47, further comprising a sulfur source selected from the group consisting of sulfates, disulfides, thiols, mercaptans, derivatives thereof and combinations thereof.

54. A semiconductor structure comprising:
a conductive layer disposed on a barrier layer disposed in a substrate;
an activation-alloy layer disposed on the conductive layer; and
a CoW alloy layer disposed on the activation-alloy.

55. The semiconductor structure of claim 54, wherein the activation-alloy layer comprises at least two elements selected from the group consisting of copper, cobalt, palladium, ruthenium and combinations thereof.

56. The semiconductor structure of claim 55, wherein the conductive layer comprises copper.

57. The semiconductor structure of claim 55, wherein the activation-alloy layer has a copper concentration range from about 50 ppm to about 1,000 ppm.

58. The semiconductor structure of claim 55, further comprising at least one element selected from the group consisting of tungsten, boron, phosphorus, sulfur and combinations thereof.

59. The semiconductor structure of claim 58, wherein the activation-alloy layer has a thickness of about 100 Å or less.

60. The semiconductor structure of claim 54, wherein the CoW alloy layer comprises cobalt and at least one element selected from the group consisting of tungsten, boron, phosphorus and combinations thereof.

61. The semiconductor structure of claim 60, wherein the CoW alloy layer has a thickness of about 500 Å or less.

62. The semiconductor structure of claim 60, wherein the activation-alloy layer comprises PdCuS and the CoW alloy layer comprises CoWBP.

63. The semiconductor structure of claim 59, wherein the activation-alloy layer is deposited by process selected from the group consisting of ALD, ion implantation and electroless deposition.

64. A method for depositing a capping layer for a semiconductor device, comprising:
performing an ALD process to form a ruthenium-containing activation layer on a copper layer disposed on a substrate surface; and
exposing a capping solution to the substrate surface to deposit the capping layer on the ruthenium-containing activation layer.

65. The method of claim 64, wherein the ALD process comprises:
positioning a substrate within a process chamber;
exposing a ruthenium-containing compound to the substrate surface, purging the process chamber with a purge gas;
exposing a chemical reagent to the substrate surface to chemical reduce the ruthenium-containing compound with and form a ruthenium layer on the substrate surface; and
purging the process chamber with the purge gas.

66. The method of claim 65, wherein the ruthenium-containing compound is selected from the group consisting of pentadienylruthenium compounds, bis(dialkylpentadienyl)ruthenium compounds, bis(alkylpentadienyl)ruthenium compounds, bis(pentadienyl)ruthenium compounds, and combinations thereof;

67. The method of claim 66, wherein the ruthenium-containing compound comprises at least one alkyl group selected from the group consisting of methyl, ethyl, propyl, butyl and combinations thereof.

68. The method of claim 67, wherein the at least one alkyl group is methyl.

69. The method of claim 67, wherein the ruthenium-containing compound is selected from the group consisting of bis(2,4-dimethylpentadienyl)ruthenium, bis(2,4-diethylpentadienyl)ruthenium, bis(2,4-diisopropylpentadienyl)ruthenium, bis(2,4-ditertbutylpentadienyl)ruthenium, bis(methylpentadienyl)ruthenium, bis(ethylpentadienyl)ruthenium, bis(isopropylpentadienyl)ruthenium, bis(tertbutylpentadienyl)ruthenium, and combinations thereof.

70. The method of claim 69, wherein the chemical reagent comprises one or more compounds selected from the group consisting of oxygen, nitrous oxide, nitric oxide, nitrogen dioxide, and combinations thereof.

71. The method of claim 69, wherein the chemical reagent comprises one or more compounds selected from the group consisting of hydrogen, ammonia, silane, disilane, trisilane, tetrasilane, dimethylsilane, methyl silane, ethylsilane, chlorosilane, dichlorosilane, hexachlorodisilane, borane, diborane, triborane, tetraborane, pentaborane, triethylborane, derivatives thereof and combinations thereof.
